(19) United States
(12) Patent Application Publication
(10) Pub. No.: US 2016/0252815 A1
(43) Pub. Date: Sep. 1, 2016

(54) Photoresist with Floating-OOB-Absorption Additive

(71) Applicant: Taiwan Semiconductor Manufacturing Company, Ltd., Hsin-Chu (TW)

(72) Inventors: Yu-Chung Su, Hsinchu City (TW); Ching-Yu Chang, Yilang County (TW)

(21) Appl. No.: 14/632,603

(22) Filed: Feb. 26, 2015

(51) Int. Cl. G03F 7/09; G03F 7/38; G03F 7/32; H01L 21/027; G03F 7/20

(52) U.S. Cl. CPC G03F 7/091; H01L 21/0274; G03F 7/20; G03F 7/2004; G03F 7/32; G03F 7/38

(57) ABSTRACT

Methods and materials for making a semiconductor device are described. The method includes forming an out-of-bond-wavelength (OOB)-reduction photoresist over a substrate, forming a floating region adjacent to a top surface of the OOB-reduction photoresist. The floating region has a higher absorbance of the OOB wavelength than a bulk region of the OOB-reduction photoresist that is below the floating region. The method also includes exposing the OOB-reduction photoresist to a radiation beam, wherein an OOB radiation portion of the radiation beam is absorbed in the floating region.

### BACKGROUND

The semiconductor integrated circuit (IC) industry has experienced rapid growth in the past several decades. Technological advances in semiconductor materials and design have produced increasingly smaller and more complex circuits. These material and design advances have been made possible as the technologies related to processing and manufacturing have also undergone technical advances. As a size of the smallest component has decreased, numerous challenges have risen. High resolution lithography processes are often one of the more important areas to decreasing feature size, and improvements in this area are generally desired. One lithography technique is extreme ultraviolet (EUV) lithography. Other techniques include X-Ray lithography, ion beam projection lithography, electron beam projection lithography, and multiple electron beam maskless lithography.

During a lithography process, some out of band (OOB) radiation causes image contrast loss. Therefore, a method of lithography process and a structure of a coating material utilized in the lithography process are desired to address the above issues.

### BRIEF DESCRIPTION OF THE DRAWINGS

Aspects of the present disclosure are best understood from the following detailed description when read in association with the accompanying figures. It is noted that, in accordance with the standard practice in the industry, various features in the drawings are not drawn to scale. In fact, the dimensions of illustrated features may be arbitrarily increased or decreased for clarity of discussion.

FIG. 1A is a diagram showing an illustrative photo-resist exposure process, according to one example of principles described herein.

FIG. 1B illustrates a schematic view of a photoresist constructed in accordance with some embodiments.

FIG. 2 illustrates a schematic view of a floating-OOB-absorption (fOOBa) additive constructed in accordance with some embodiments.

FIGS. 3A to 3B illustrate an OOB absorption agent of FIG. 2, constructed in accordance with some embodiments.

FIGS. 4A to 4F illustrates a floating agent of FIG. 2, constructed in accordance with some embodiments.

FIG. 5 illustrates a fOOBa additive constructed in accordance with some embodiments.

FIG. 6 is a flowchart of a method for making a semiconductor device in one embodiment according to various aspects of the present disclosure.

FIGS. 7 to 9 are cross-sectional views of a semiconductor device at various fabrication stages, constructed in accordance with the method of FIG. 6.

### DETAILED DESCRIPTION

It is understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The present disclosure provides a lithography method for use in manufacturing a semiconductor device. The terms lithography, immersion lithography, photolithography, and optical lithography may be used interchangeably in the present disclosure. Photolithography is a process used in micro-fabrication, such as semiconductor fabrication, to selectively remove parts of a thin film or a substrate. The process uses light to transfer a pattern (e.g., a geometric pattern) from a photomask to a light-sensitive layer (e.g., photoresist, or simply “resist”) on the substrate. The light causes a chemical change in exposed regions of the light-sensitive layer, which may increase or decrease solubility of the exposed regions. If the exposed regions become more soluble, the light-sensitive layer is referred to as a positive photoresist. If the exposed regions become less soluble, the light-sensitive layer is referred to as a negative photoresist. Baking processes may be performed before or after exposing the substrate, such as a post-exposure baking process. A developing process selectively removes the exposed or unexposed regions with a developing solution creating an exposure pattern over the substrate. A series of chemical treatments may then engrave/etch the exposure pattern into the substrate (or material layer), while the patterned photoresist protects regions of the underlying substrate (or material layer). Alternatively, metal deposition, ion implantation, or other processes can be carried out. Finally, an appropriate reagent removes (or strips) the remaining photoresist and the substrate are ready for the whole process to be repeated for the next stage of circuit fabrication. In a complex integrated circuit (for example, a modern CMOS), a substrate may go through the photolithographic cycle a number of times.

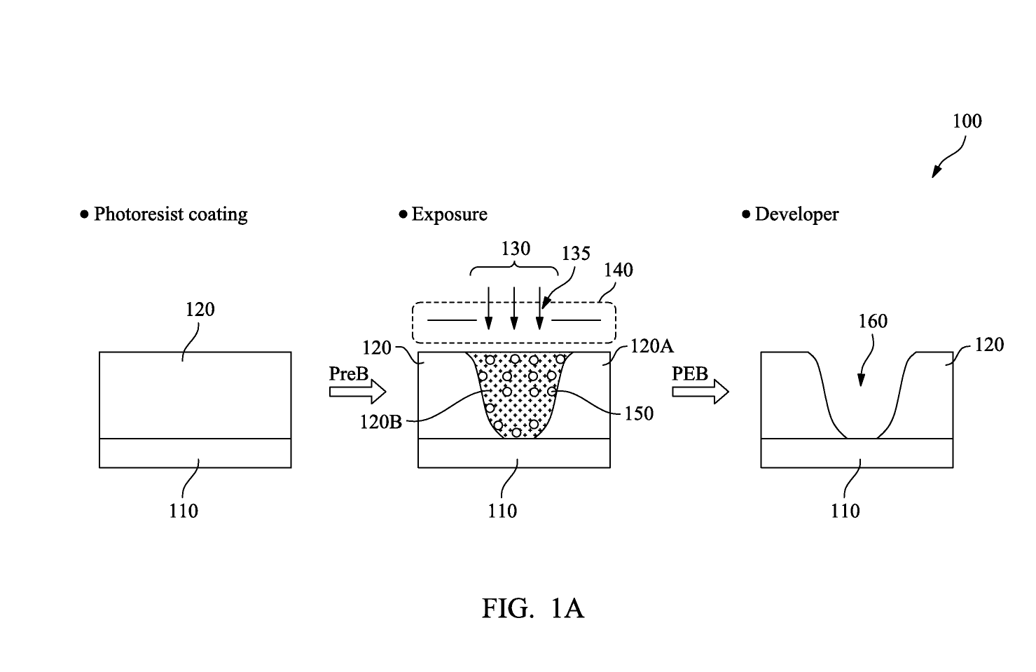

FIG. 1A is a diagram showing an illustrative photoresist exposure process 100. The process 100 involves coating a photoresist 120 over a substrate 110. In some embodiments, the substrate 110 includes silicon. In some other embodiments, the substrate 110 may alternatively or additionally include other suitable semiconductor material, such as germanium (Ge), silicon germanium (SiGe), silicon carbide (SiC), gallium arsenic (GaAs), diamond, indium arsenide (InAs), indium phosphide (InP), silicon germanium carbide (SiGeC), and gallium indium phosphide (GaInP). The substrate 110 may also include various features such as various doped regions, shallow trench isolation (STI) regions, source/drain features, gate stacks, dielectric features, and/or multilevel interconnects.

Referring to FIG. 1B, the photoresist 120 is disposed over the substrate 110 by a suitable technique, such as a spin-coating technique. The photoresist 120 may contain a photoacid generator (PAG) 124 and an acid-labile group (ALG) 126. When absorbing photo energy, the PAG 124 decomposes and forms an amount of acid. In some embodiments, the ALG is covalently bonded or attached to a backbone of a polymer of the photoresist. The backbone of the polymer may be poly(hydroxystyrene) (PHS), methacrylate, or a PHS/methacrylate hybrid. The photoresist 120 may be a positive-type or negative-type resist material and may have a multi-layer structure.

Examples of the PAG 124, that is, a compound capable of generating an acid upon exposure, are given below. It should be understood that they may be used alone or in admixture of two or more. Suitable PAGs include onium salts, selenium salts, phosphonium salts, iodonium, sulfonium salts, organic halogen compounds, O-nitrobenzylsulfonate compounds, N-iminosulfonate compounds, N-imidosulfonate compounds, diazosulfonate compound, sulfonimide compounds, diazodisulfonate compounds, and disulfone compounds.

In some embodiment, the ALG 126 is a compound that combines the function of both the ALG and a base. The base may include a nitrogen-containing base selected from any suitable base including an amine (—NH₂, —NHR), sulfonium amines (—SO₂NH₂, —SO₂NHR), —CONH₂, —CONHR, —CSNH₂, —C═CNH₂, —C═CNHR, pyridine-NH₂, phenyl-NH₂, pyrrole-NH₂, or thiophene-NH₂, where R represents an alkyl, aryl, substituted alkyl, substituted aryl, hetero aromatic ring, hetero atom, cyclic group, or substituted cyclic group. In some embodiments, the ALG-base compound 126 includes a bulky unit with a tertiary carbon as a good leaving group. The ALG-base compound 126 may be selected from esters, t-butyl, tert-butoxycarbonyl, iso-norbornyl, 2-methyl-2-adamantyl, 2-ethyl-2-adamantyl, 3-tetrahydrofuran (THF), lactone, 2-THF, or the 2-tetrahydropyranyl (THP) group. In various embodiments, the ALG-base compound 126 includes a cross-linker site that can cross-link with the photoresist polymer after thermal baking. In other embodiments, the ALG-base compound 126 does not include a cross-linker site and diffuses after thermal baking.

The photoresist 120 may also include a solvent 128. The solvent 128 may be partially evaporated by a soft baking process. In some embodiments, the solvent 128 includes propylene glycol monomethyl ether, propylene glycol monopropyl ether, ethyl lactate, cyclohexanone, methyl ethyl ketone, dimethyl formamide, alcohol (e.g., isopropyl alcohol or ethanol), or other suitable solvent.

The photoresist 120 may also include a number of additives that will assist the photoresist 120 obtain the highest resolution. For example, the photoresist 120 may also include surfactants in order to help improve the ability of the photoresist 120 to coat the surface on which it is applied. For another example, the photoresist 120 may also include a quencher, which maybe utilized to inhibit diffusion of the generated acids/bases/free radicals within the photoresist, which helps the resist pattern configuration as well as to improve the stability of the photoresist 120 over time. Yet for another example, the photoresist 120 may also include a stabilizer, which assists in preventing undesired diffusion of the acids generated during exposure of the photoresist 120.

Referring back to FIG. 1A, the photoresist 120 is then exposed to a radiation beam 135 from a light source 130, through a photomask (mask or reticle) 140. The photomask 140 has a predefined pattern. The exposure process will result in a photoresist pattern that includes a plurality of exposed regions such as exposed features and a plurality of unexposed regions. FIG. 1A illustrates the photoresist layer 120 in varying shades. The lighter color regions 120A illustrate regions that were blocked from the light source 130 and thus no acid was created. The darker color region 120B represents region that were exposed to light, causing an acid creating chemical reaction. The light source 130 may be a variety of sources, including a deep ultra-violet (DUV) source. In one example, the light source 130 may be an extreme ultraviolet (EUV) light source. In some examples, other light sources 130 such as electron beam (e-beam) writing. Alternatively, the exposure process may utilize other radiation beams, such as ion beam, x-ray, and other proper exposure energy. Additionally, a pre-bake of the photoresist 120 may be performed prior to the exposure process in order to cure and dry the photoresist 120.

During exposure the PAG will generate acid 150 and deprotect ALG which is bonded on the polymer. The solubility of the photoresist 120 may be increased for positive tone photoresist (i.e., the acid will cleave an acid cleavable polymer, resulting in the polymer becoming more hydrophilic) and decreased for negative tone resist (i.e., the acid will catalyze an acid catalyzed crosslinkable polymer, resulting in the polymer becoming more hydrophobic).

Subsequently, the photoresist 120 may be subjected to a post-exposure bake (PEB) and then developed by any suitable process to form a pattern in the photoresist 120. After a pattern exposure and/or PEB process, the PAG in the photoresist 120 produces the acid 150, which increases or decreases polymer solubility. The solubility may be increased for positive tone resist (i.e., the acid will cleave an acid cleavable polymer, resulting in the polymer becoming more hydrophilic) and decreased for negative tone resist (i.e., the acid will catalyze an acid catalyzed crosslinkable polymer, resulting in the polymer becoming more hydrophobic).

The PAG 124 may be added to the photoresist 120 in amounts of about 1 percent to about 7 percent of the total weight of the photoresist. Providing about 7 percent or more may help ensure that excessive exposure is not required. Providing about 7 percent or less may help avoid decreases in light transmission of the resist composition.

The ALG 126 works to control concentration of the acid 150 in both the exposed and unexposed areas of the photoresist layer. Acid 150 generated by the PAG in the exposure area reacts with the ALG to deprotect the ALG, and in the case of a positive tone resist, the polarity of the resist polymer can become more hydrophilic. The ALG 126 can also neutralize excess acid 150 and prevent acid 150 from diffusing to unexposed areas. In the non-exposed areas, the ALG 126 buffers or neutralizes the acid that diffuses from the exposure area to improve the acid contrast between exposed and unexposed areas.

Subsequently, a developing solution may be utilized to remove portions of the photoresist 120. The developing solution may remove the exposed or unexposed portions depending on the resist type. If the photoresist 120 comprises a negative-type resist, the exposed portions are not dissolved by the developing solution and remain over the substrate. If the photoresist layer 120 includes a positive-type resist, the exposed portions would be dissolved by a positive-tone developing solution, leaving the unexposed portions behind. With a negative-tone developing solution, the unexposed portions would be dissolved, leaving the exposed portions. The remaining exposed portions (or unexposed portions) define a pattern.

Although existing methods of lithography have been generally adequate for their intended purposes, they have not been entirely satisfactory in all respects. For example, the light source 130 is an EUV light source produced by plasma, such as DPP (discharge-produced plasma) and LPP (laser-produced plasma), emits some out of band (OOB) radiation. An OOB radiation is a radiation with a wavelength which is out of a pre-determined wavelength band centered on a pre-determined wavelength, such as out of a 2% band centered on a target 13.5 nm. For example, an OOB radiation has a wavelength between about 200 nm and about 300 nm, and usually at about 248 nm, referred to as a deep ultraviolet (DUV) OOB radiation. When an EUV photoresist is exposed to OOB radiation, an unwanted background exposure of the photoresist, called “flare” , may be formed and have an adverse impact on the resolution of the photoresist. To suppress OOB, several techniques have been developed. One of current common techniques is to use a filter to filter out the OOB radiation. In order to preserve EUV light and lithography performance, the filter usually needs to be made very thin and uniform, a durability and cost of the filter, as well as EUV light loss, raise challenges. Another one of current common techniques is to coat an extra layer upon photoresist, which can absorb OOB light. However it needs extra tool and cost to another coating. The present disclosure provides lithography process with an OOB-reduction photoresist.

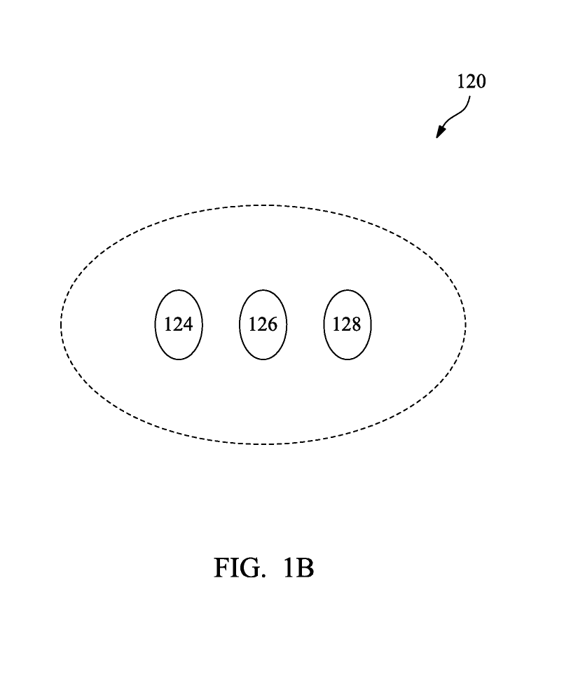

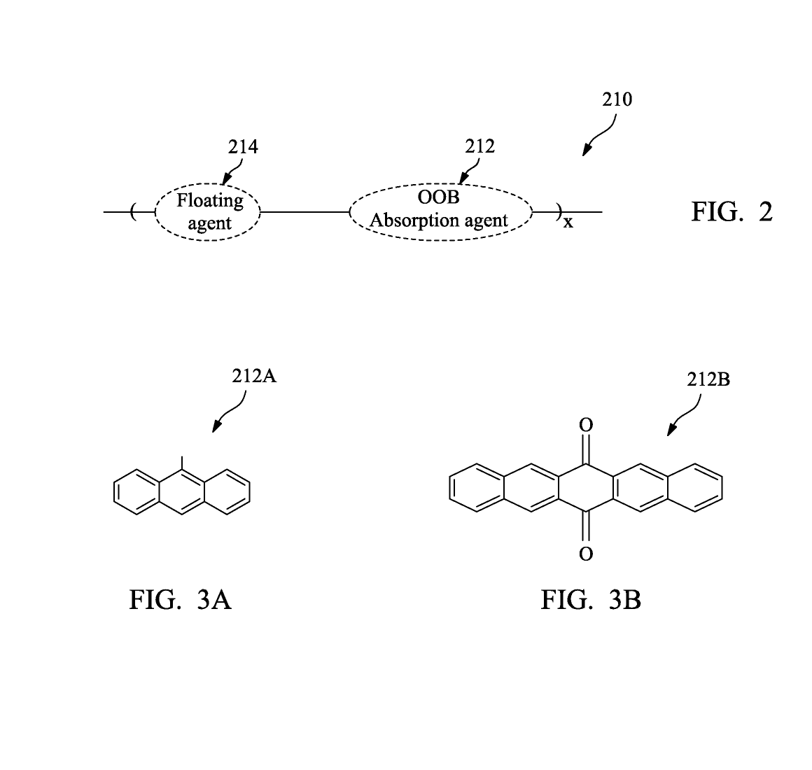

FIG. 2 is a schematic view of a f-OOB-a (fOOBa) additive 210 in accordance with some embodiments. The f-OOB-a additive 210 includes an OOB absorption (OOBa) agent 212, which has a high absorbance of OOB radiation. In the present embodiment, the OOBa agent 212 includes one or more aromatic structures. In some embodiment, the OOBa agent 212 may include functionalized anthracene 212A (as shown in FIG. 3A), and/or 6,13-pentacenequinone 212B (as shown in FIG. 3B), such as described by U.S. Patent Publication No. 2006/023000, the entire disclosure of which is incorporated herein by reference.

Structures of the OOBa agent 212 may be chosen according with respect to OOB radiation wavelength range. For example, FIGS. 3A and 3B show exemplary OOBa agents. FIG. 3A, shows one example of an OOBa agent 212, namely anthracene structure 212A that has a high absorbance at a range between about 220 nm and about 260 nm of OOB radiation. FIG. 3B shows another example of an OOBa agent 212, namely 6,13 pentacenequinone structure 212B that has a high absorbance at a range between about 300 nm and about 400 nm of OOB radiation.

The f-OOB-a additive 210 also includes a floating agent 214. The floating agent refers to the floating agent 214 being part of a component of a polymeric solution that is able to float to a top portion of the polymeric solution such as when the polymeric solution is coated on a substrate. In some other embodiments, the floating agent 214 includes at least one of fluorine atom or alkyl fluoride, which can make the floating agent 214 more floatable. In some embodiment, the floating agent 214 includes at least one of hydroxyl, carboxyl, amine, amide group, alkyl, fluoro, benzyl group. For example, the floating agent 214 includes at least one alkyl group that further includes CF₃, C₂F₅, C₃F₇ or a combination thereof. The alkyl fluoride groups may be straight, branch, cyclic, or any combination thereof. In some other embodiment, the floating agent 214 may include fluoro alcohol and developer switchable form hydrophobic to hydrophilic.

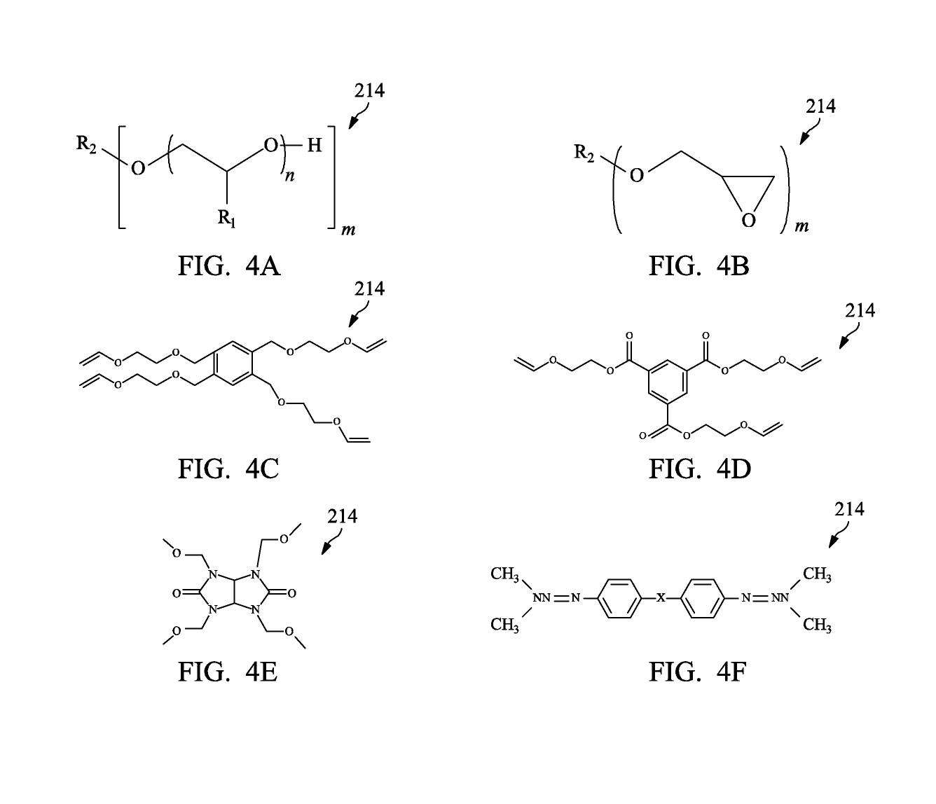

FIGS. 4A-4F provide examples of suitable floating agent 214, those are described in U.S. Publication No. 2014/0273457, the entire disclosure of which is incorporated herein by reference. In an embodiment, the floating agent 214 may have the general structure shown in FIG. 4A, which includes a cross-linkable functional group in between the brackets. R₁ represents a hydrogen atom or an alkyl group having 1 to 20 carbon atom(s), and R₂ represents an alkyl group having 1 to 20 carbon atom(s), an alkenyl group having 2 to 8 carbon atoms, an alkynyl group having 2 to 12 carbon atoms, an alkylcarbonyl group having 2 to 12 carbon atoms, an alkylcarbonylamino group having 2 to 12 carbon atoms, an alkyloxyalkyl group having 2 to 12 carbon atoms, an alkylamino group having 1 to 12 carbon atom(s), an alkyldiamino group having 1 to 12 carbon atom(s) or any combination thereof. Here N is an integer from 1 to 200, and m is an integer from 2 to 10. The cross-linkable functional group can create a covalent bond with the floating agent 214 and form a linear or branched polymer structure.

A specific example of a suitable floating agent 214 is shown in FIG. 4B, where the cross-linkable functional group is a glycidyl ether. Here M is an integer from 2 to 10. R₂ in FIG. 4B may be an alkyl group with a hydrogen attached to a hydrocarbon with a straight, branched, or cyclic structure. The alkyl group may also contain one or more hetero atoms. For example, it may further contain nitrogen or oxygen. The structure in FIG. 4B may include a fluorine atom or alkyl fluoride. For example, at least one the alkyl groups may include one or more of CF₃, C₂F₅, or C₃F₇. In various embodiments, the glycidyl ether group may be replaced by an alkyl oxide, alkene, alkyne, or other cross-linkable functional group, as shown in FIGS. 4C-4F, where X is O, SO₂, NH, or a linear or branched alkyl group having 1 to 20 carbon atom(s).

Other forms of the floating agent 214 may be used in accordance with principles described herein. For example, the floating agent 214 is a chosen solvent, which has a high affinity to the OOBa agent 212. Therefore the fOOBa additive 210 has a high volatile ability and it makes the fOOBa additive 210 floatable. For another example, the floating agent 214 is a floatable polymer and it has high affinity to the OOBa agent 212.

Referring again to FIG.2, in the present embodiment, the OOBa agent 212 and the floating agent 214 are coupled together into a chemical segment. In some embodiments, this chemical segment may be repeated multiple times, such as x times where x is an integer. Thus, the fOOBa additive 210 has both of OOB absorption function and floating function. The OOBa agent 212 may be coupled with the floating agent 214 by chemical bond, covalent bond, a hydrogen bond, or an ionic bond.

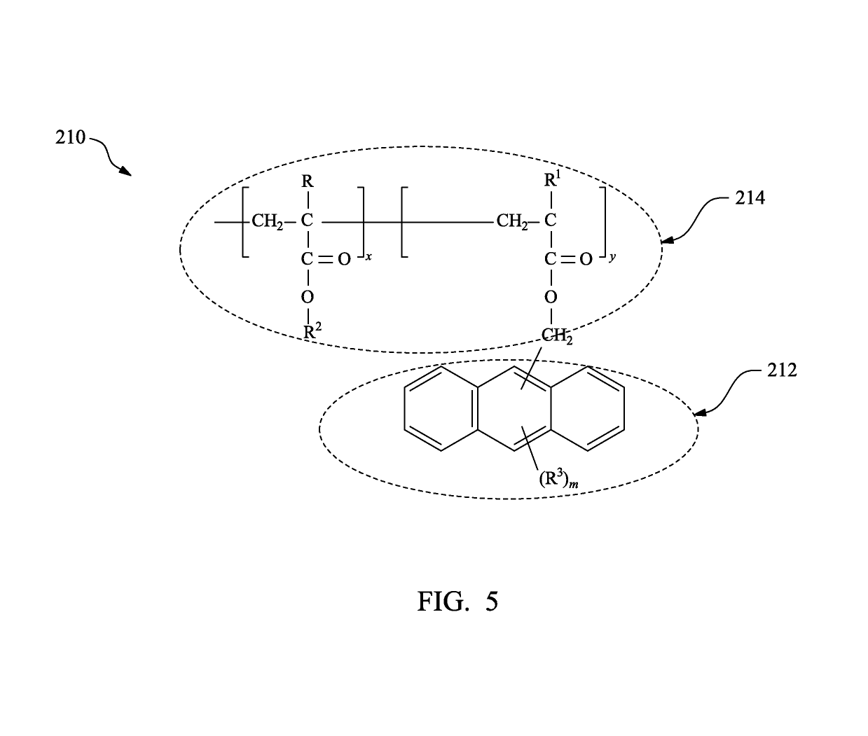

FIG. 5 provides example of the OOBa agent 212 bonded to the floating agent 214 by a chromophore bound. In various embodiments, the floating agent 214 includes an acrylic, polyester, epoxy novolac, polysaccharide, polyether, polyimide, polyurethane, or mixtures thereof. Each R and R¹ are independently a hydrogen or a substituted or unsubstituted alkyl group having from 1 to 8 carbon atom(s); each R² is an independently substituted or unsubstituted alkyl group having 1 to 10 carbon atom(s) (e.g., 1 to 6 carbons); R³ in the OOBa 212 may be independently halogen (e.g., F, Cl, or Br), an alkyl group having 1 to 8 carbon atom(s), alkoxy group having 1 to 8 carbon atom(s), alkynyl group having 2 to about 8 carbon atom(s), cyano group, or nitro group. M is an integer from 0 to 9 (e.g., 0, 1, or 2); x is the mole fraction or percent of alkyl acrylate units in the polymer (e.g., about 10 to about 80 percent); and y is the mole fraction or percent of anthracene units in the polymer (e.g., about 5-10 to 90 percent).

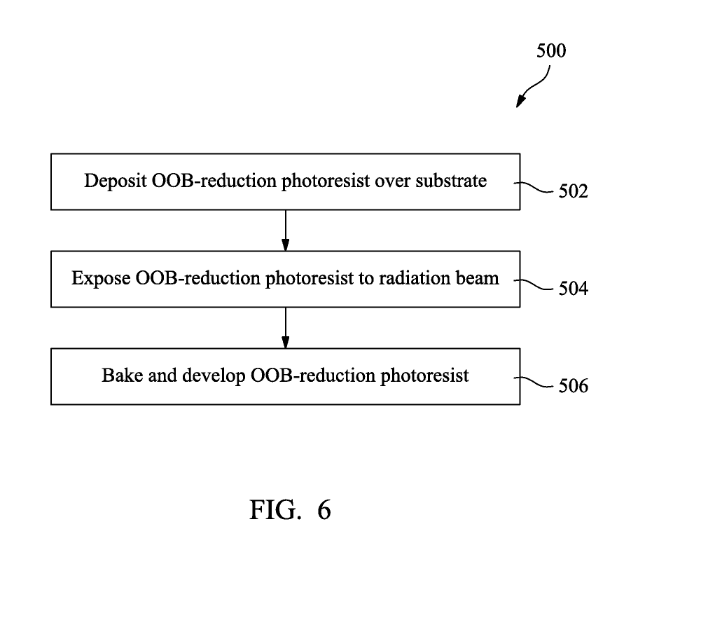

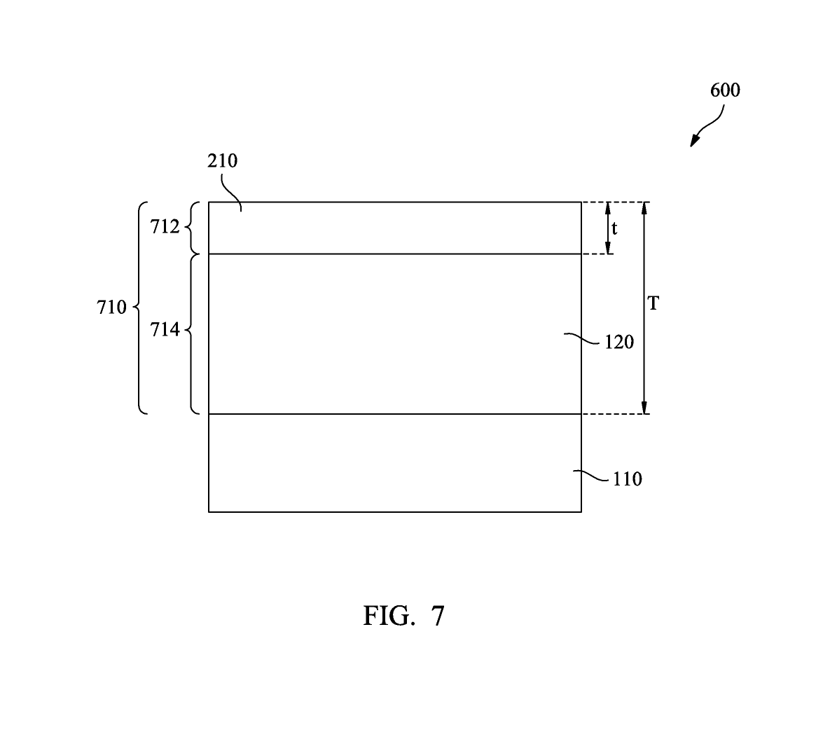

FIG. 6 illustrates a flowchart of a method 500 to utilize the fOOBa additive 210 and the photoresist 120 in a semiconductor fabrication, constructed in accordance with some embodiments. FIGS. 7-9 are cross-sectional views of a semiconductor structure 600 in accordance with some embodiments.

Referring to FIGS. 6 and 7, the method 500 starts at step 502 by depositing an OOB-reduction photoresist 710 over the substrate 110, such as using a spin-coating technique. The OOB-reduction photoresist 710, as its name suggests, works to reduce adverse impact of the OOB radiation on a photoresist. In the present embodiment, the OOB-reduction photoresist 710 includes photoresist 120 and the fOOBa additive 210. The photoresist 120 includes the PAG 124 and ALG 126 and the solvent 128. In one embodiment, the photoresist 120 is an EUV photoresist. The fOOBa additive 210 is incorporated into the photoresist 120, such as by blending.

As described in FIG.1B, the photoresist 120 includes the PAG 124, the ALG 126 and the solvent 128. As also described in FIG.2, the fOOBa additive 210 includes the OOBa agent 212 and the floating agent 214.

In the present embodiment, the fOOBa additive 210 moves to the top of the OOB-reduction photoresist layer 710 as it is being applied, e.g., in the spin-on process. This movement may be initiated by a high surface energy of fluorine atoms in the floating agent 214. This high surface energy, coupled with the low interaction between the fluorine atoms and the other atoms within the OOB-reduction photoresist 710, will initiate the movement of the floating agent 214 with the OOBa agent 212 together to the top surface of the OOB-reduction photoresist 710. Thus, the OOB-reduction photoresist layer 710 includes a floating region 712 and a bulk region 714 (below the floating region 712) over the substrate 110. As illustrated in FIG. 7, the fOOBa additive 210 is more concentrated in the floating region 712 compared to the bulk region 714, where the photoresist 120 is the dominated material. In one embodiment, a thickness t of the floating region 712 is in a range of about 5% to 50% of a total thickness T of the OOB-reduction photoresist 710.

However, using the floating agent 214 is not the only method or material that may be used to form the floating region 712. Rather, any suitable material and method that are involved in inducing floating to the top surface of the OOB-reduction photoresist layer 710 and form the floating region 712 may alternatively be used. All such materials and methods are fully intended to be included within the scope of the embodiments. For example, the fOOBa additive 210 is formed to have a proper polarity such that the fOOBa additive 210 has different affinity and the phase separation may happened after the OOB-reduction photoresist layer 710 being coated.

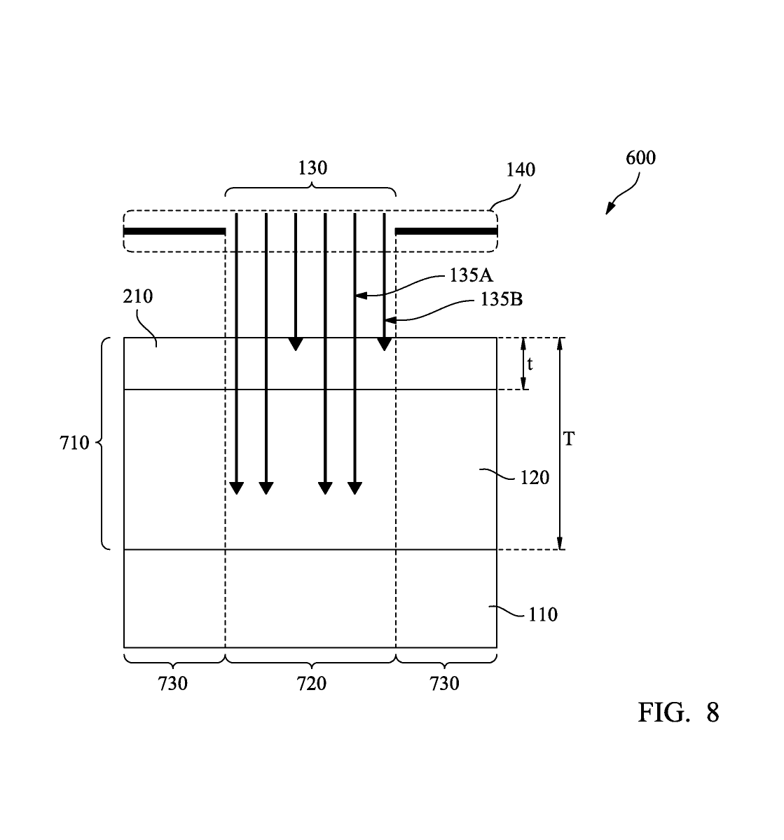

Referring to FIGS. 6 and 8, the OOB-reduction photoresist layer 710 is then exposed to the radiation beam 135 from the light source 130, through the photomask (mask or reticle) 140 having a predefined pattern . It results in a photoresist pattern that includes a plurality of exposed regions 720 such as exposed features and a plurality of unexposed regions 730. In the present embodiment, the light source 130 includes an EUV light source and the radiation beam 135 includes an EUV radiation beam 135A and an OOB radiation beam 135B. In the exposed region 720, at least a majority of the OOB radiation beam 135B is absorbed by the fOOBa additive 210 while the EUV beam 135A passes through the fOOBa additive 210 and reaches to the photoresist 120 to create an effective solubility switch between exposed and unexposed regions, 720 and 730. Thus, since a majority of the OOB radiation beam 135B is absorbed in the floating region 720, a formation of photo image in the bulk region 720 is mainly formed by reaction between the photoresist 120 and the EUV beam 135A.

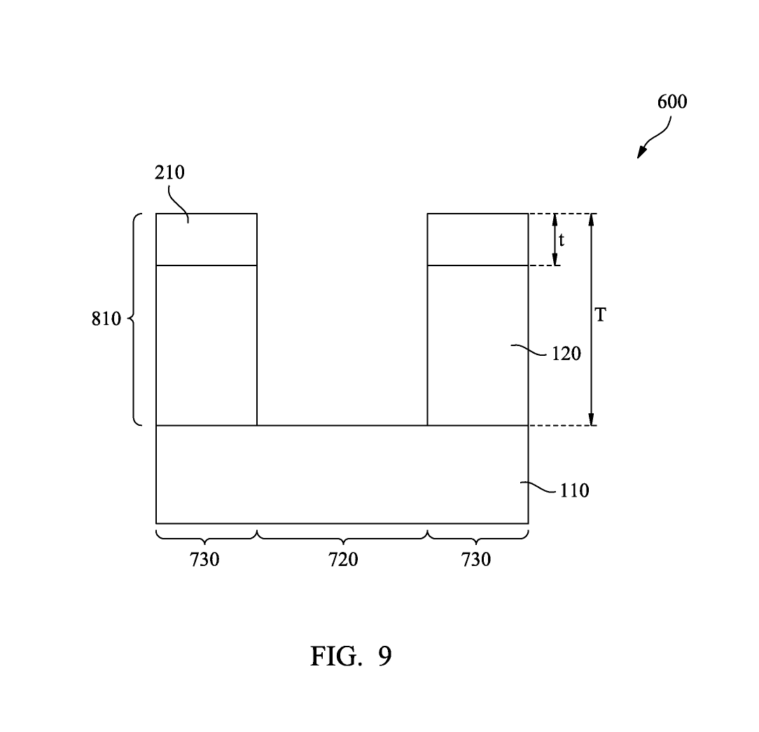

Referring to FIGS. 6 and 9, subsequently, the OOB-reduction photoresist layer 710 is subjected to a post-exposure bake (PEB) and developed by any suitable process to form a patterned OOB-reduction photoresist layer 810. An example of a developing solution is tetramethylammonium hydroxide (TMAH). Any concentration level of TMAH developer solution may be utilized, such as approximately 2.38% TMAH developer solution. The developing solution may remove the exposed or unexposed portions of the OOB-reduction photoresist 710, depending on the resist type. For example, if the OOB-reduction photoresist 710 comprises a negative-type resist, the exposed portions are not dissolved by the developing solution and remain over substrate 45. If the OOB-reduction photoresist 710 includes a positive-type resist, the exposed portions are dissolved by the developing solution, leaving the unexposed portions behind.

Additional steps may be implemented before, during, and after the method 500, and some steps described above may be replaced or eliminated for other embodiments of the method 500.

Based on the above, the present disclosure offers methods for lithography process. The method employs applying an OOB-reduction photoresist over a substrate and forming a floating region by floating up a floating-OOB-absorption (fOOBa) additive to a top surface of the OOB-reduction photoresist. The fOOBa additive has a high absorbance of the OOB wavelength. The method demonstrates decreasing adverse impact of the OOB radiation and prevents lithography deterioration.

One of the broader forms of the present disclosure relates to a method of making a semiconductor device. The method includes forming an out-of-bond-wavelength (OOB)-reduction photoresist over a substrate, forming a floating region adjacent to a top surface of the OOB-reduction photoresist. The floating region has a higher absorbance of the OOB wavelength than a bulk region of the OOB-reduction photoresist that is below the floating region. The method also includes exposing the OOB-reduction photoresist to a radiation beam, wherein an OOB radiation portion of the radiation beam is absorbed in the floating region.

Another one of the broader forms of the present disclosure involves another method of making a semiconductor device. The method includes spin-coating an out-of-bond-wavelength (OOB)-reduction extreme ultraviolet (EUV) photoresist over a substrate, forming a floating region is formed adjacent to a top surface of the OOB-reduction EUV photoresist. The floating region has a higher absorbance of the OOB wavelength than a rest region of the OOB-reduction EUV photoresist. The method also includes exposing the OOB-reduction EUV photoresist to an EUV radiation beam. An OOB radiation portion of the EUV radiation beam is absorbed in the floating region. The method also includes baking the OOB-reduction EUV photoresist and applying a developer to the OOB-reduction EUV photoresist.

The present disclosure also describes a photoresist used in photolithography patterning. The photoresist includes a floating agent coupled with the out-of-bond-wavelength-absorption agent. The photoresist also includes an out-of-bond-wavelength-absorption agent coupled with the floating agent. The out-of-bond-wavelength-absorption agent has a high absorbance of the out-of-bond-wavelength. Therefore the out-of-bond-wavelength-absorption agent is capable to float up with the floating agent to a top surface of the photoresist when the photoresist being applied.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A method comprising:
forming an out-of-extreme-ultraviolet-band (OOB)-reduction photoresist over a substrate, which includes forming a floating region adjacent to a top surface of the OOB-reduction photoresist, wherein the floating region has a higher absorbance of OOB wavelengths than a bulk region of the OOB-reduction photoresist that is below the floating region,
wherein the OOB-reduction photoresist includes an OOB-absorption agent bonded with a floating agent, the floating agent having at least an alkyl group that includes C₂F₅ or C₃F₇; and
exposing the OOB-reduction photoresist to a EUV radiation beam, wherein an OOB radiation portion of the EUV radiation beam is absorbed in the floating region.

2. (canceled)

3. The method of claim 1, wherein
the OOB-absorption agent floats up with the floating agent to the top surface of the OOB-reduction photoresist when it is applied over the substrate.

4. The method of claim 3, wherein bonds between the OOB-absorption agent and the floating agent comprise a covalent bond, a hydrogen bond, or an ionic bond.

5. The method of claim 1, wherein the forming of the floating region includes:
mixing the OOB-absorption agent with a solvent, wherein the OOB-absorption agent obtains a high volatile ability by having a high affinity to the solvent; and
the OOB-absorption agent floats up to form the floating region.

6. The method of claim 1, wherein the OOB-absorption agent includes one or more aromatic structures.

7. The method of claim 1, wherein the forming of the OOB-reduction photoresist over the substrate uses a spin-coating technique.

8. (canceled)

9. The method of claim 1, further comprising:
after exposing the OOB-reduction photoresist, baking the OOB-reduction photoresist; and
applying a developer to the OOB-reduction photoresist.

10. A method comprising:
spin-coating an out-of-extreme-ultraviolet-band (OOB)-reduction extreme ultraviolet (EUV) photoresist over a substrate, wherein the OOB-reduction EUV photoresist includes an OOB-absorption agent bonded with a floating agent, the floating agent having at least an alkyl group that includes C₂F₅ or C₃F₇;
forming a floating region adjacent to a top surface of the OOB-reduction EUV photoresist, wherein the floating region has a higher absorbance of the OOB wavelengths than another region of the OOB-reduction EUV photoresist that is below the floating region;
exposing the OOB-reduction EUV photoresist to an EUV radiation beam, wherein an OOB radiation portion of the EUV radiation beam is absorbed in the floating region;
baking the OOB-reduction EUV photoresist; and
applying a developer to the OOB-reduction EUV photoresist.

11. (canceled)

12. The method of claim 10, wherein
the OOB-absorption agent floats up with the floating agent to the top surface of the OOB-reduction EUV photoresist when it is applied over the substrate.

13. The method of claim 12, wherein bonds between the OOB-absorption agent and the floating agent comprise a covalent bond, a hydrogen bond, a chromophore bond, or an ionic bond.

14. The method of claim 10, wherein the forming of the floating region includes:
mixing the OOB-absorption agent with a solvent, wherein the OOB-absorption agent obtains a high volatile ability by having a high affinity to the solvent; and
wherein the OOB-absorption agent floats up to form the floating region.

15. The method of claim 10, wherein the OOB-absorption agent includes one or more aromatic structures.

16. The method of claim 10, wherein the floating region is formed having a thickness, which is less than about 50% of a total thickness of the OOB-reduction EUV photoresist.

17. A photoresist comprising:
a backbone polymer;
an acid labile group (ALG) bonded to the backbone polymer;
a photo acid generator (PAG);
a solvent;
a surfactant; and
an additive that includes a floating agent bonded with an out-of-extreme-ultraviolet-band(OOB)-absorption agent, wherein the OOB-absorption agent has a high absorbance of OOB wavelengths, wherein the OOB-absorption agent is capable to float up with the floating agent to a top surface of the photoresist when the photoresist is applied to a substrate, wherein the OOB-absorption agent includes one or more aromatic structures, and the floating agent includes at least an alkyl group, wherein the alkyl group includes C₂F₅ or C₃F₇.

18. (canceled)

19. (canceled)

20. The photoresist of claim 17, wherein the OOB-absorption agent is bonded with the floating agent by a covalent bond, hydrogen bond, or ionic bond.

21. The method of claim 3, wherein the OOB-absorption agent includes an aromatic structure.

22. The method of claim 6, wherein the OOB-absorption agent and the floatable polymer include following structure: 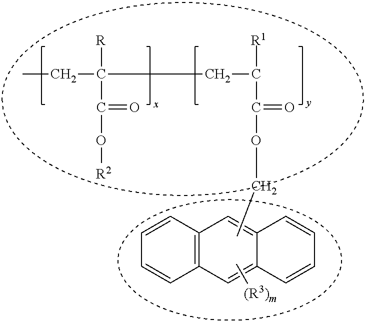
wherein each of R and R¹ is independently a hydrogen or an alkyl group having 1 to 8 carbon atom(s); R² is an alkyl group having 1 to 10 carbon atom(s); R³ is a halogen, an alkyl group having 1 to 8 carbon atom(s), an alkoxy group having 1 to 8 carbon atom(s), an alkynyl group having 2 to about 8 carbon atom(s), a cyano group, or a nitro group; and m is an integer from 0 to 9.

23. (canceled)

24. The method of claim 1, wherein the floating region has a thickness less than a thickness of the bulk region.

25. The method of claim 10, wherein the OOB-reduction EUV photoresist includes: a backbone polymer, an acid labile group (ALG) bonded to the backbone polymer, a photo acid generator (PAG), a solvent, and a surfactant.

26. The method of claim 1, wherein the OOB wavelengths are within a range from about 200 nm to about 400 nm.
